(19) United States
(12) Patent Application Publication
(10) Pub. No.: US 2014/0082450 A1
(43) Pub. Date: Mar. 20, 2014

(54) Systems and Methods for Efficient Transfer in Iterative Processing

(71) Applicants: Shaohua Yang, Santa Clara, CA (US); Wu Chang, Santa Clara, CA (US); Razmik Karabed, San Jose, CA (US); Victor Krachkovsky, Allentown, PA (US)

(72) Inventors: Shaohua Yang, Santa Clara, CA (US); Wu Chang, Santa Clara, CA (US); Razmik Karabed, San Jose, CA (US); Victor Krachkovsky, Allentown, PA (US)

(73) Assignee: LSI Corp., Milpitas, CA (US)

(21) Appl. No.: 13/621,341

(22) Filed: Sep. 17, 2012

(51) Int. Cl. H03M 13/11

(52) U.S. Cl. CPC H03M 13/1154
USPC 714/758

(57) ABSTRACT

Embodiments of the present inventions are related to systems and methods for data processing, and more particularly to systems and methods for format efficient data processing.

### BACKGROUND

Embodiments of the present inventions are related to systems and methods for data processing, and more particularly to systems and methods for format efficient data processing.

Various data transfer systems have been developed including storage systems, cellular telephone systems, radio transmission systems. In each of the systems data is transferred from a sender to a receiver via some medium. For example, in a storage system, data is sent from a sender (i.e., a write function) to a receiver (i.e., a read function) via a storage medium. Data is transferred from the sender to the receiver and in many cases includes padding designed to assure codewords fit within defined boundaries. Such padding allows for space efficient encoding and decoding, but wastes bandwidth.

Hence, for at least the aforementioned reasons, there exists a need in the art for advanced systems and methods for data processing.

### BRIEF SUMMARY

Embodiments of the present inventions are related to systems and methods for data processing, and more particularly to systems and methods for format efficient data processing.

Various embodiments of the present invention provide data processing systems that include one or both of a data encoding circuit and a data encoding circuit. Such data encoding circuits include: a first data encoder circuit, a bit padding circuit, a second data encoder circuit, a bit purging circuit, and a data decoder circuit. The first data encoder circuit is operable to encode a data set to yield a first encoded output that includes at least one element beyond the end of a desired boundary. The bit padding circuit is operable to add at least one element to the first encoded output to yield a padded output complying with the desired boundary. The second data encoder circuit is operable to encode the padded output to yield a second encoded output. The bit purging circuit is operable to eliminate the at least one element beyond the end of the desired boundary and the at least one element added to the first encoded output from the second encoded output to yield a purged output. Such data decoding circuits are operable to: receive a first decoder input corresponding to the purged output; reconstruct a second decoder input corresponding to the second encoded output; and apply a data decoding algorithm to the second decoder input to yield a decoded output.

This summary provides only a general outline of some embodiments of the invention. The phrases “in one embodiment,” “according to one embodiment,” “in various embodiments”, “in one or more embodiments”, “in particular embodiments” and the like generally mean the particular feature, structure, or characteristic following the phrase is included in at least one embodiment of the present invention, and may be included in more than one embodiment of the present invention. Importantly, such phases do not necessarily refer to the same embodiment. Many other embodiments of the invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 shows a storage system including bit purging data encoding and reconstruction data decoding circuitry in accordance with various embodiments of the present invention;

FIG. 2 depicts a data transmission system including bit purging data encoding and reconstruction data decoding circuitry in accordance with one or more embodiments of the present invention;

FIGS. 3a-3e shows an encoder circuit including bit purging data encoding circuitry in accordance with some embodiments of the present invention;

FIGS. 4a-4b shows a data processing circuit including data reconstruction circuitry in accordance with some embodiments of the present invention;

FIG. 5 is a flow diagram showing a bit purging based data encoding process in accordance with one or more embodiments of the present invention; and

FIGS. 6a-6b are flow diagrams showing a method for data reconstruction based data processing in accordance with some embodiments of the present invention.

### DETAILED DESCRIPTION OF SOME EMBODIMENTS

Embodiments of the present inventions are related to systems and methods for data processing, and more particularly to systems and methods for format efficient data processing.

Various embodiments of the present invention provide data processing systems that include: a first data encoder circuit, a bit padding circuit, a second data encoder circuit, a bit purging circuit, and a data decoder circuit. The first data encoder circuit is operable to encode a data set to yield a first encoded output that includes at least one element beyond the end of a desired boundary. The bit padding circuit is operable to add at least one element to the first encoded output to yield a padded output complying with the desired boundary. The second data encoder circuit is operable to encode the padded output to yield a second encoded output. The bit purging circuit is operable to eliminate the at least one element beyond the end of the desired boundary and the at least one element added to the first encoded output from the second encoded output to yield a purged output. The data decoder circuit is operable to: receive a first decoder input corresponding to the purged output; reconstruct a second decoder input corresponding to the second encoded output; and apply a data decoding algorithm to the second decoder input to yield a decoded output.

In some instances of the aforementioned embodiments, the system further includes a data detector circuit operable to apply a data detection algorithm to a detector input corresponding to the purged output to yield a detected output. In such instances, the first decoder input is derived from the detected output. In some cases, the decoded output is a first decoded output, the detected output is a first detected output, and the data decoder circuit is further operable to provide a second decoded output including elements of the first decoded output corresponding to the detected output, and to provide a third decoded output including elements of the first decoded output corresponding to the at least one element added to the first encoded output to yield the padded output. In such cases, the data detector circuit is further operable to re-apply the data detection algorithm to the detector input guided by the second decoded output to yield a second detected output. In particular cases, the data decoder circuit is further operable to: receive a third decoder input corresponding to the second detected output; scale the third decoded output to yield a scaled output; augment the third decoder input with the scaled output to yield a fourth decoder input; and re-apply the data decoding algorithm to the fourth decoder input to yield a fourth decoded output.

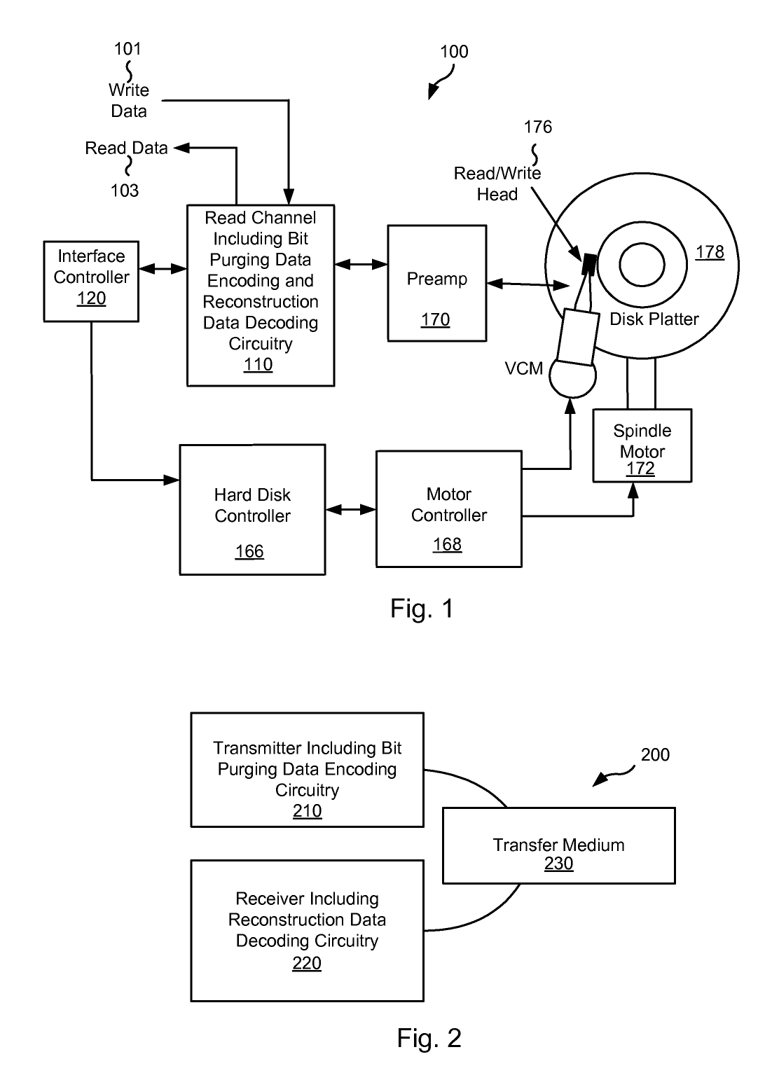

Turning to FIG. 1, a storage system 100 including a read channel circuit 110 having bit purging data encoding and reconstruction data decoding circuitry is shown in accordance with various embodiments of the present invention. Storage system 100 may be, for example, a hard disk drive. Storage system 100 also includes a preamplifier 170, an interface controller 120, a hard disk controller 166, a motor controller 168, a spindle motor 172, a disk platter 178, and a read/write head 176. Interface controller 120 controls addressing and timing of data to/from disk platter 178, and interacts with a host controller 190 that includes out of order constraint command circuitry. The data on disk platter 178 consists of groups of magnetic signals that may be detected by read/write head assembly 176 when the assembly is properly positioned over disk platter 178. In one embodiment, disk platter 178 includes magnetic signals recorded in accordance with either a longitudinal or a perpendicular recording scheme.

In a typical read operation, read/write head assembly 176 is accurately positioned by motor controller 168 over a desired data track on disk platter 178. Motor controller 168 both positions read/write head assembly 176 in relation to disk platter 178 and drives spindle motor 172 by moving read/write head assembly to the proper data track on disk platter 178 under the direction of hard disk controller 166. Spindle motor 172 spins disk platter 178 at a determined spin rate (RPMs). Once read/write head assembly 176 is positioned adjacent the proper data track, magnetic signals representing data on disk platter 178 are sensed by read/write head assembly 176 as disk platter 178 is rotated by spindle motor 172. The sensed magnetic signals are provided as a continuous, minute analog signal representative of the magnetic data on disk platter 178. This minute analog signal is transferred from read/write head assembly 176 to read channel circuit 110 via preamplifier 170. Preamplifier 170 is operable to amplify the minute analog signals accessed from disk platter 178. In turn, read channel circuit 110 decodes and digitizes the received analog signal to recreate the information originally written to disk platter 178. This data is provided as read data 103 to a receiving circuit. A write operation is substantially the opposite of the preceding read operation with write data 101 being provided to read channel circuit 110. This data is then encoded and written to disk platter 178.

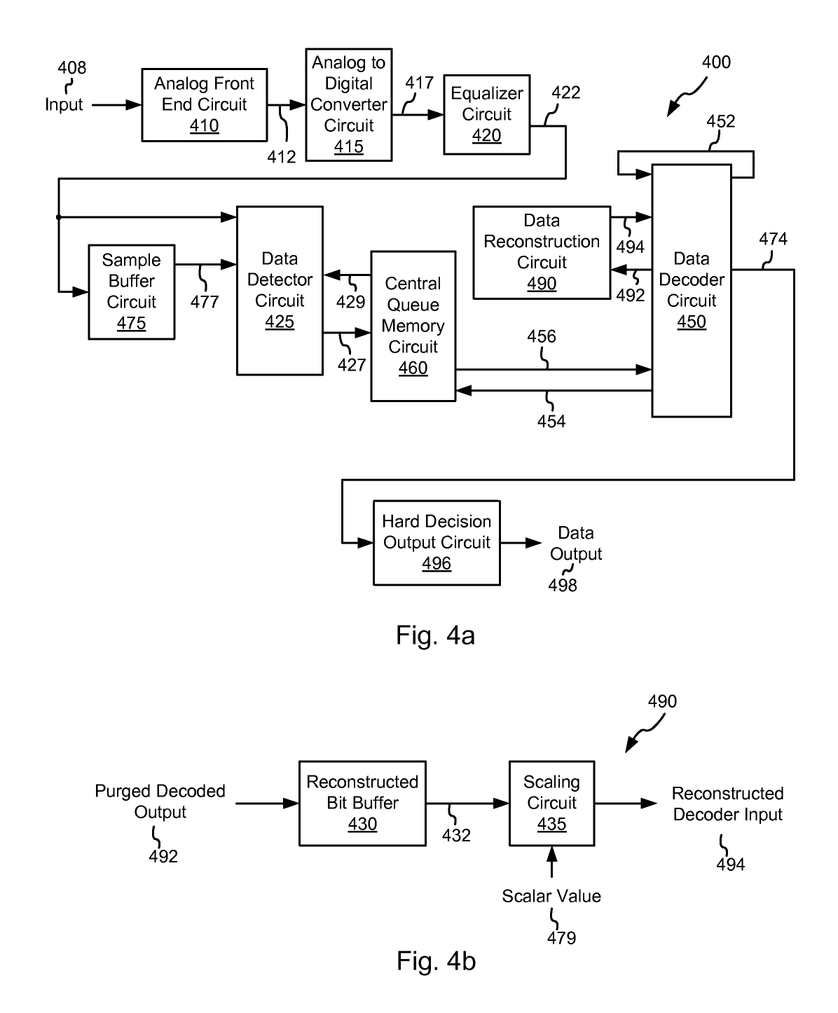

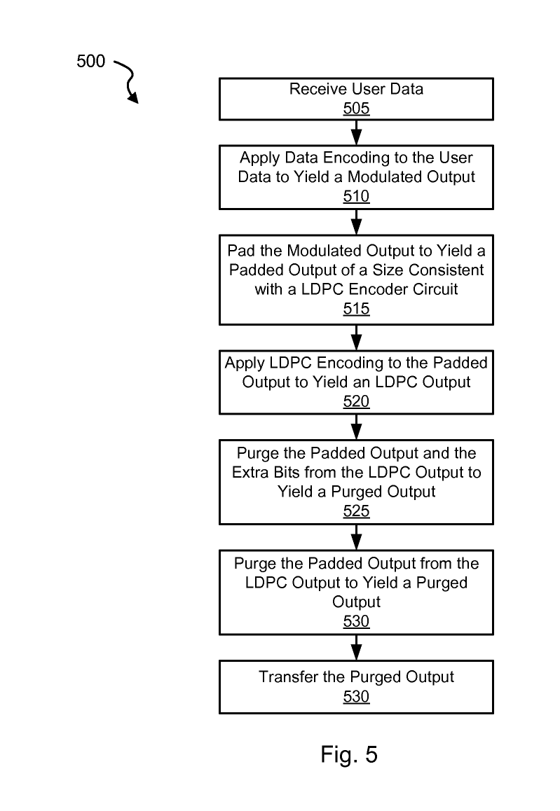

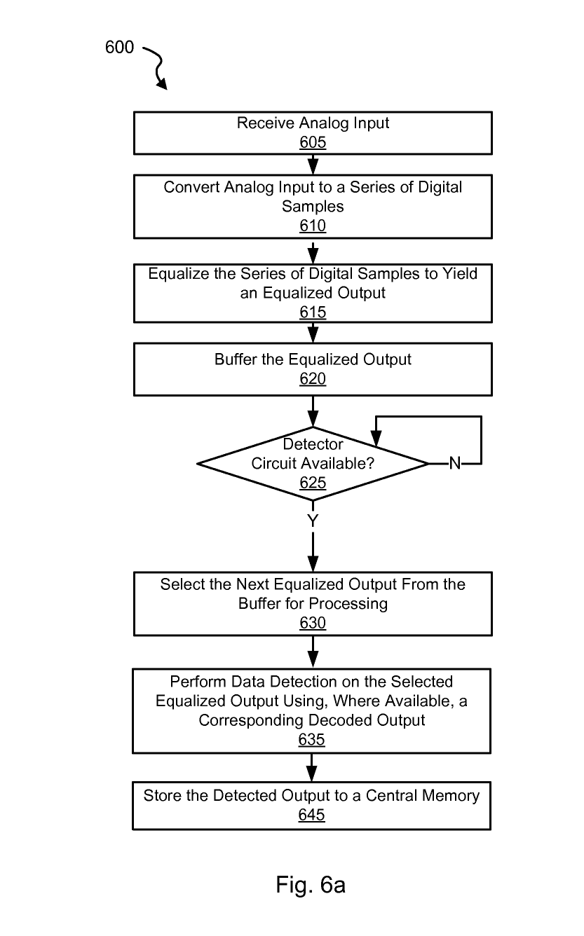

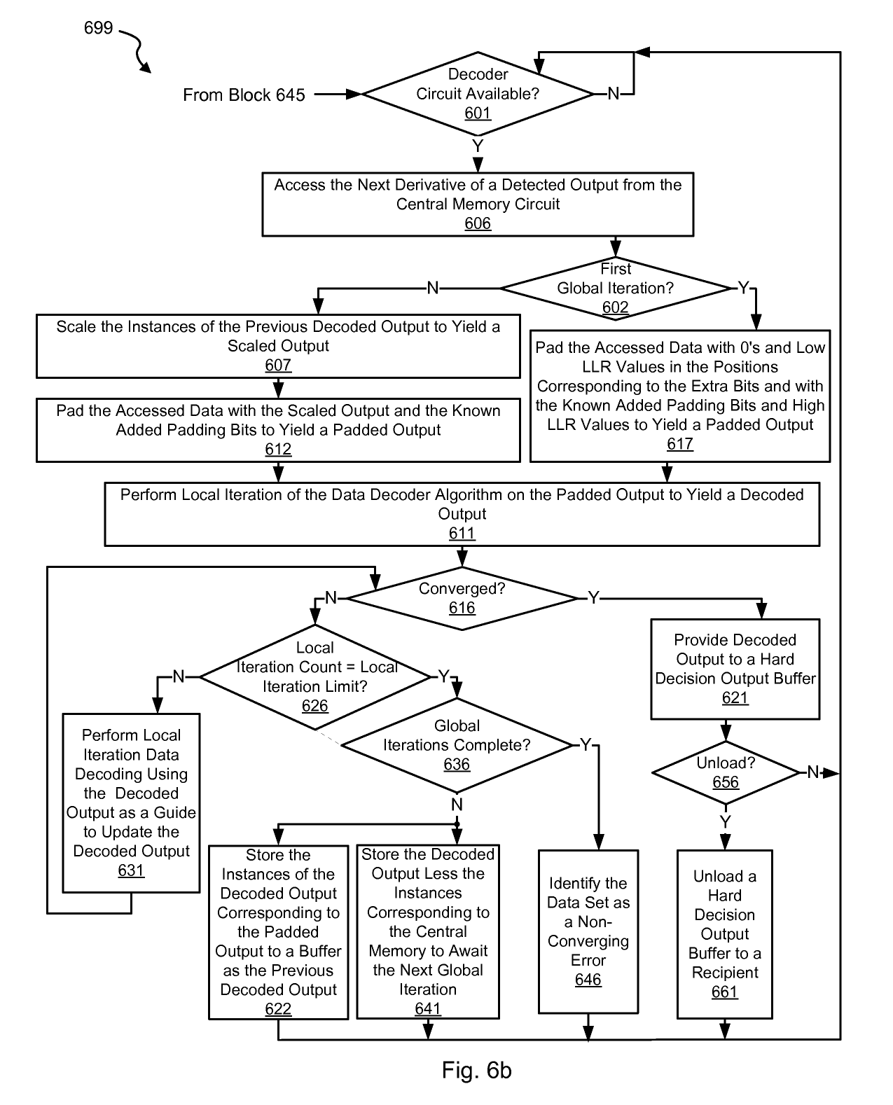

As part of transferring data to disk platter 178, data encoding is applied to a user data set resulting in an encoded data set that includes one or more elements beyond a desired boundary requirement of an LDPC encoder circuit. Additional padding bits are added to the encoded data sets to yield a padded output that matches the boundary requirement of an LDPC encoder circuit. The LDPC encoder circuit applies LDPC encoding to yield an LDPC encoded output. The padding bits and the one or more elements beyond the desired boundary requirement of the LDPC encoder circuit are purged to make a purged output. This purged output is then processed for transfer to disk platter 178. The purged output is re-read from disk platter 178 and processed. This processing includes applying a data detection algorithm to the purged output to yield a detected output. Padding data corresponding to the information deleted during the purging process is added to allow for processing. This data is re-processed during repeated global iterations in an attempt to regenerate the originally written data set. In some cases, the read channel circuit may be implemented similar to that discussed in relation to FIGS. 3a and 4a-4b; and/or may operate similar to the methods discussed below in relation to FIGS. 5 and 6a-6b.

It should be noted that storage system 100 may be integrated into a larger storage system such as, for example, a RAID (redundant array of inexpensive disks or redundant array of independent disks) based storage system. Such a RAID storage system increases stability and reliability through redundancy, combining multiple disks as a logical unit. Data may be spread across a number of disks included in the RAID storage system according to a variety of algorithms and accessed by an operating system as if it were a single disk. For example, data may be mirrored to multiple disks in the RAID storage system, or may be sliced and distributed across multiple disks in a number of techniques. If a small number of disks in the RAID storage system fail or become unavailable, error correction techniques may be used to recreate the missing data based on the remaining portions of the data from the other disks in the RAID storage system. The disks in the RAID storage system may be, but are not limited to, individual storage systems such as storage system 100, and may be located in close proximity to each other or distributed more widely for increased security. In a write operation, write data is provided to a controller, which stores the write data across the disks, for example by mirroring or by striping the write data. In a read operation, the controller retrieves the data from the disks. The controller then yields the resulting read data as if the RAID storage system were a single disk.

A data decoder circuit used in relation to read channel circuit 110 may be, but is not limited to, a low density parity check (LDPC) decoder circuit as are known in the art. Such low density parity check technology is applicable to transmission of information over virtually any channel or storage of information on virtually any media. Transmission applications include, but are not limited to, optical fiber, radio frequency channels, wired or wireless local area networks, digital subscriber line technologies, wireless cellular, Ethernet over any medium such as copper or optical fiber, cable channels such as cable television, and Earth-satellite communications. Storage applications include, but are not limited to, hard disk drives, compact disks, digital video disks, magnetic tapes and memory devices such as DRAM, NAND flash, NOR flash, other non-volatile memories and solid state drives.

In addition, it should be noted that storage system 100 may be modified to include solid state memory that is used to store data in addition to the storage offered by disk platter 178. This solid state memory may be used in parallel to disk platter 178 to provide additional storage. In such a case, the solid state memory receives and provides information directly to read channel circuit 110. Alternatively, the solid state memory may be used as a cache where it offers faster access time than that offered by disk platted 178. In such a case, the solid state memory may be disposed between interface controller 120 and read channel circuit 110 where it operates as a pass through to disk platter 178 when requested data is not available in the solid state memory or when the solid state memory does not have sufficient storage to hold a newly written data set. Based upon the disclosure provided herein, one of ordinary skill in the art will recognize a variety of storage systems including both disk platter 178 and a solid state memory.

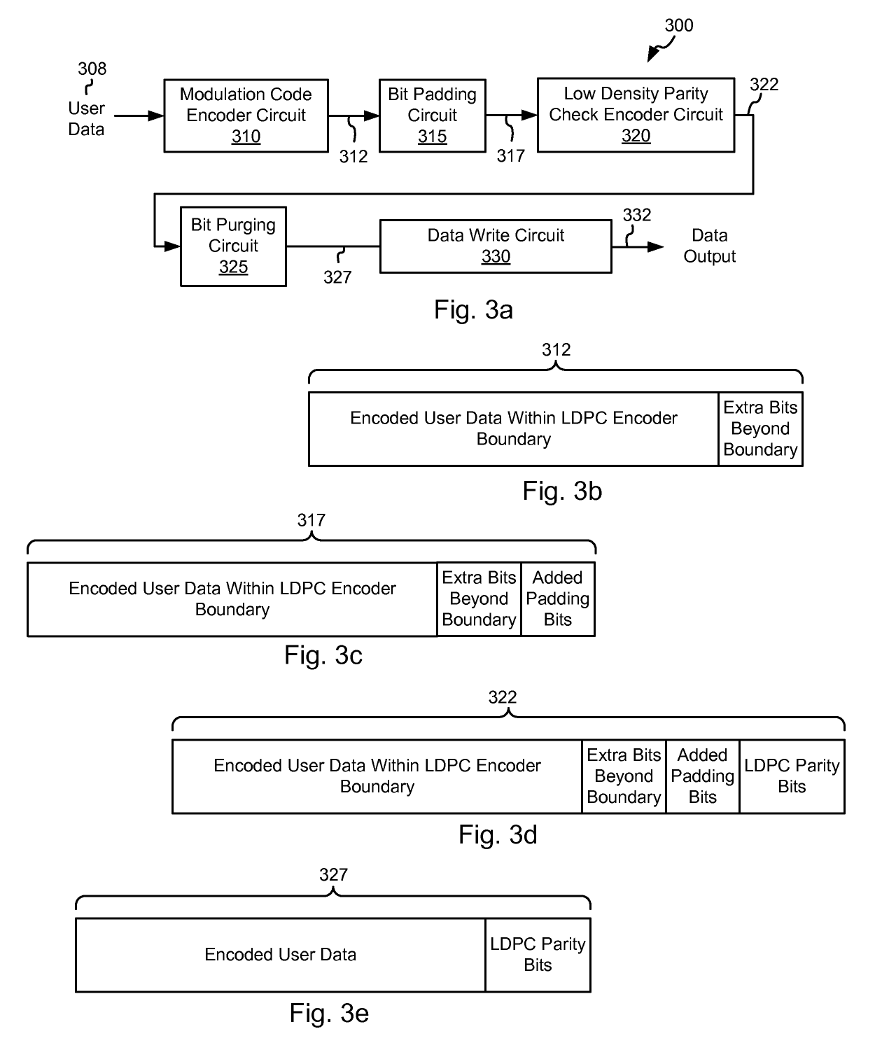

Turning to FIG. 2, a data transmission system 200 including a receiver 220 having reconstruction data decoding circuitry, and a transmitter including bit purging data encoding circuitry in accordance with one or more embodiments of the present invention. Transmitter 210 applies data encoding to a user data set resulting in an encoded data set that includes one or more elements beyond a desired boundary requirement of an LDPC encoder circuit. Additional padding bits are added to the encoded data sets to yield a padded output that matches the boundary requirement of an LDPC encoder circuit. The LDPC encoder circuit applies LDPC encoding to yield an LDPC encoded output. The padding bits and the one or more elements beyond the desired boundary requirement of the LDPC encoder circuit are purged to make a purged output. This purged output is then processed for transfer via transfer medium 230. The purged output is received by receiver 220 and processed. This processing includes applying a data detection algorithm to the purged output to yield a detected output. Padding data corresponding to the information deleted during the purging process is added to allow for processing. This data is re-processed during repeated global iterations in an attempt to regenerate the originally written data set. In some cases, transmitter 210 may include circuitry similar to that discussed in relation to FIGS. 3a-3d, and receiver 220 may include circuitry similar to that discussed in relation to FIGS. 4a-4b. Data transmission system 200 may operate similar to the methods discussed below in relation to FIGS. 5 and 6a-6b.

Turning to FIG. 3a, an encoding circuit 300 including bit purging circuitry is shown in accordance with some embodiments of the present invention. Encoding circuit 300 includes a modulation code encoder circuit 310. In one particular embodiment of the present invention, modulation code encoder circuit 310 is operable to apply run length limited encoding to a received user data 308. Based upon the disclosure provided herein, one of ordinary skill in the art will recognize a variety of encoding that may be applied by modulation code encoder circuit 310 in accordance with different embodiments of the present invention. Modulation code encoder circuit 310 provides the result of encoding user data 308 as an encoded output 312.

A low density parity check encoder circuit 320 is designed to operate data sets of a defined size. In one particular embodiment of the present invention, low density parity check encoder circuit 320 is designed to operate on twelve element data sets. In some cases, the elements are individual bits. In other cases, the elements are multi-bit symbols. A bit padding circuit 315 is operable to add one or more bits or elements to encoded output 312 to yield a padded output 317 that aligns with the designed boundary conditions of low density parity check encoder circuit 320. For example, if low density parity check encoder circuit 320 is designed to operate on twelve bit data sets, and encoded output 312 modulo twelve is ‘n’, then bit padding circuit 375 appends (12-n) padding bits to the end of encoded output 312 to yield padded output 317 to assure that the length of padded output 317 is an integral number of twelve bit data sets where n is greater than zero. Of note, padding is not added where n is equal to zero. Thus, where, for example, n is three, then nine bits are appended by the bit padding circuit 375. FIG. 3b graphically depicts an example of encoded output 312 where it includes an integral number of data sets of size accepted by low density parity check encoder circuit 320 (i.e., encoded user data within LDPC encoder boundary), and extra bits beyond the boundary (i.e., n). FIG. 3c graphically depicts an example of padded output 317 where it includes the integral number of data sets of size accepted by low density parity check encoder circuit 320 (i.e., encoded user data within LDPC encoder boundary), the extra bits beyond the boundary (i.e., n), and added padding bits (data set size -n).

Returning to FIG. 3a, low density parity check encoder circuit 320 applies an LDPC encoding algorithm to padded output 317 to yield an LDPC encoded output 322. LDPC encoded output 322 generates a number of parity bits that are included with padded output 317 to yield LDPC encoded output 322. FIG. 3d graphically depicts an example of LDPC decoded output 322 including the integral number of data sets of size accepted by low density parity check encoder circuit 320 (i.e., encoded user data within LDPC encoder boundary), the extra bits beyond the boundary (i.e., n), the added padding bits (data set size -n), and the added parity bits. Returning to FIG. 3a, low density parity check encoder circuit 320 provides LDPC encoded output to a bit purging circuit 325 that is operable to eliminate the added padding bits (data size-n) and the extra bits beyond the boundary (i.e., n) leaving a purged output 327. Bit purging circuit 327 may be any circuit capable of eliminating one or more selected elements of a data set to yield a reduced data set. FIG. 3e graphically depicts an example of purged output 327 including the integral number of data sets of size accepted by low density parity check encoder circuit 320 (i.e., encoded user data within LDPC encoder boundary), and the added parity bits. Returning to FIG. 3a, purged output 327 is provided to a data write circuit 330. Data write circuit 330 includes circuitry designed to format purged output 327 for transfer via a transfer medium. This transfer medium may be, but is not limited to, a storage medium or a communication medium.

Turning to FIG. 4a, a data processing circuit 400 is shown that includes data reconstruction circuitry in accordance with some embodiments of the present invention. Data processing circuit 400 includes an analog front end circuit 410 that receives an analog signal 408. Analog front end circuit 410 processes analog signal 408 and provides a processed analog signal 412 to an analog to digital converter circuit 415. Analog front end circuit 410 may include, but is not limited to, an analog filter and an amplifier circuit as are known in the art. Based upon the disclosure provided herein, one of ordinary skill in the art will recognize a variety of circuitry that may be included as part of analog front end circuit 410. In some cases, analog input signal 408 is derived from a read/write head assembly (not shown) that is disposed in relation to a storage medium (not shown). In other cases, analog input signal 408 is derived from a receiver circuit (not shown) that is operable to receive a signal from a transmission medium (not shown). The transmission medium may be wired or wireless. Based upon the disclosure provided herein, one of ordinary skill in the art will recognize a variety of source from which analog input signal 408 may be derived.

Analog to digital converter circuit 415 converts processed analog signal 412 into a corresponding series of digital samples 417. Analog to digital converter circuit 415 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments of the present invention. Digital samples 417 are provided to an equalizer circuit 420. Equalizer circuit 420 applies an equalization algorithm to digital samples 417 to yield an equalized output 422. In some embodiments of the present invention, equalizer circuit 420 is a digital finite impulse response filter circuit as are known in the art. It may be possible that equalized output 422 may be received directly from a storage device in, for example, a solid state storage system. In such cases, analog front end circuit 410, analog to digital converter circuit 415 and equalizer circuit 420 may be eliminated where the data is received as a digital data input. Equalized output 422 is stored to a sample buffer circuit 475 that includes sufficient memory to maintain one or more codewords until processing of that codeword is completed through a data detector circuit 425 and a data decoder circuit 450 including, where warranted, multiple “global iterations” defined as passes through both data detector circuit 425 and a data decoder circuit 450 and/or “local iterations” defined as passes through data decoding circuit 450 during a given global iteration. Sample buffer circuit 475 stores the received data as buffered data 477.

Buffered data 477 is provided to data detector circuit 425 that applies a data detection algorithm to the received input to yield a detected output 427. Data detector circuit 425 may be any data detector circuit known in the art that is capable of producing a detected output 427. As some examples, data detector circuit 425 may be, but is not limited to, a Viterbi algorithm detector circuit or a maximum a posteriori detector circuit as are known in the art. Based upon the disclosure provided herein, one of ordinary skill in the art will recognize a variety of data detector circuits that may be used in relation to different embodiments of the present invention. Detected output 425 may include both hard decisions and soft decisions. The terms “hard decisions” and “soft decisions” are used in their broadest sense. In particular, “hard decisions” are outputs indicating an expected original input value (e.g., a binary ‘1’ or ‘0’, or a non-binary digital value), and the “soft decisions” indicate a likelihood that corresponding hard decisions are correct. Based upon the disclosure provided herein, one of ordinary skill in the art will recognize a variety of hard decisions and soft decisions that may be used in relation to different embodiments of the present invention.

Detected output 427 is provided to a central queue memory circuit 460 that operates to buffer data passed between data detector circuit 425 and data decoder circuit 450. When data decoder circuit 450 is available, data decoder circuit 450 receives detected output 427 from central queue memory 460 as a decoder input 456 along with a reconstructed decoder input 494 corresponding to elements purged during the encoding process (e.g., by bit purging circuit 325). During a first global iteration, the elements provided by a data reconstruction circuit 490 as reconstructed input 494 are set to defined values with a corresponding low soft data (e.g., log likelihood data) values indicating that the likelihood of the position being correct to be low. Data decoder circuit 450 applies a data decoding algorithm to decoder input 456 augmented with reconstructed decoder input 494 in an attempt to recover originally written data. Application of the data decoding algorithm includes passing messages between variable and check nodes as is known in the art. In most cases, the message passing includes standard belief propagation or feed forward messaging where two or more messages feeding the variable or check node are used to calculate or determine a message to be passed to another node.

The result of the data decoding algorithm yields a decoded output 452 that includes elements corresponding to decoder input 456 and elements corresponding to reconstructed decoder input 494. Similar to detected output 427, decoded output 454 may include both hard decisions and soft decisions. For example, data decoder circuit 450 may be any data decoder circuit known in the art that is capable of applying a decoding algorithm to a received input. Data decoder circuit 450 may be, but is not limited to, a low density parity check decoder circuit or a Reed Solomon decoder circuit as are known in the art. Based upon the disclosure provided herein, one of ordinary skill in the art will recognize a variety of data decoder circuits that may be used in relation to different embodiments of the present invention.

Where decoded output 452 failed to converge, the last local iteration is applied to the received decoder input for the current global iteration, and another global iteration is allowed for the received data set, the elements of decoded output 452 corresponding to decoder input 454 are written back to central memory circuit 454 to await a subsequent global iteration, and the elements of decoded output 452 corresponding to reconstructed decoder input 494 is written back to data reconstruction circuit 490 as purged decoded output 492.

Alternatively, where decoded output 452 includes the original data (i.e., the data decoding algorithm converges) or a timeout condition occurs (exceeding of a defined number of local iterations through data decoder circuit 450 and global iterations for the currently processing equalized output), data decoder circuit 450 provides the result of the data decoding algorithm as a data output 474. Data output 474 is provided to a hard decision output circuit 496 where the data is reordered before providing a series of ordered data sets as a data output 498.

One or more iterations through the combination of data detector circuit 425 and data decoder circuit 450 may be made in an effort to converge on the originally written data set. As mentioned above, processing through both the data detector circuit and the data decoder circuit is referred to as a “global iteration”. For the second and later global iteration, data reconstruction circuit 490 provides a scaled version of the elements of decoded output 452 received by data reconstruction circuit 490 as purged decoded output 492. Turning to FIG. 4b, an example implementation is shown of data reconstruction circuit 490 where purged decoded output 492 is stored to a reconstructed bit buffer 430 for use in a subsequent global iteration. Reconstructed bit buffer 430 provides a buffered output 432 to a scaling circuit 435. Scaling circuit 435 multiplies the soft data associated with buffered output 432 by a scalar value 479 to yield reconstructed decoder input 494. In some embodiments of the present invention, scalar value is user programmable, while in other cases scalar value 479 is fixed. Scalar value 479 may be any value less than unity that operates to reduce the likelihood that buffered output 432 is considered correct. In one particular embodiment of the present invention, scalar value 479 is 0.75. Applying a scalar value less than unity results in a higher probability that data decoder circuit 450 will modify reconstructed decoder input 494 on a subsequent global iteration. Of note, during subsequent global iterations, reconstructed decoder input 494 is not reprocessed through data detector circuit 425. For subsequent global iterations, data detector circuit 425 applies the data detection algorithm to buffered data 477 as guided by decoded output 454. Decoded output 454 is received from central queue memory 460 as a detector input 429.

During each global iteration it is possible for data decoder circuit 450 to make one or more local iterations including application of the data decoding algorithm to decoder input 452. For the first local iteration, data decoder circuit 450 applies the data decoder algorithm without guidance from a decoded output 452. For subsequent local iterations, data decoder circuit 450 applies the data decoding algorithm to the combination of decoder input 456 and reconstructed decoder input 494 as guided by a previous decoded output 452. In some embodiments of the present invention, a default of ten local iterations is allowed for each global iteration.

Turning to FIG. 5, a flow diagram 500 shows a bit purging based data encoding process in accordance with one or more embodiments of the present invention. Following flow diagram 500, user data is received (block 505). This user data may be any data that is to be encoded for transfer via a transfer medium. The transfer medium may be, but is not limited to, a storage medium or a communication medium. A data encoding algorithm is applied to the user data to yield a modulated output (block 510). As one example, the data encoding algorithm may be a run length limited algorithm that limits the number of consecutive instances of the same data level that are allowed in a data stream. Based upon the disclosure provided herein, one of ordinary skill in the art will recognize a variety of data encoding algorithms that may be applied to a received user data set in accordance with different embodiments of the present invention.

The modulated output is padded to yield a padded output (block 515). The amount of padding is designed to make the length of padded output an integral multiple of a defined size used by a downstream LDPC encoder circuit (block 515). As an example, if the downstream LDPC encoder circuit is designed to operate on twelve bit data sets, and the modulated output modulo twelve is ‘n’, then the bit padding appends (12-n) padding bits to the end of the modulated output to yield the padded output to assure that the length of the padded output is an integral number of twelve bit data sets where n is greater than zero. Of note, padding is not added where n is equal to zero. Thus, where, for example, n is three, then nine bits are appended by the bit padding process. Referring back to FIG. 3b, an example of a modulated output is graphically shown that includes an integral number of data sets of size accepted by the downstream LDPC encoded (i.e., encoded user data within LDPC encoder boundary), and extra bits beyond the boundary (i.e., n). FIG. 3c graphically depicts an example of a padded output where it includes the integral number of data sets of size accepted by low density parity check encoder circuit (i.e., encoded user data within LDPC encoder boundary), the extra bits beyond the boundary (i.e., n), and the added padding bits (data set size -n).

LDPC encoding is then applied to the padded output to yield an LDPC output (block 520). This LDPC encoding may be any LDPC encoding known in the art. The LDPC encoding adds a number of parity bits to the padded output. An example of the LDPC output is shown in FIG. 3d. Both the previously added padding bits and the extra bits beyond the boundary of the LDPC encoder (i.e., n) are purged or eliminated from the LDPC output to yield a purged output (block 530). An example of a purged output is shown in FIG. 3e. This purged output is then transferred (block 530). Such transfer may include, but is not limited to, writing the purged output to a storage medium or transmitting the purged data via a communication medium. Based upon the disclosure provided herein, one of ordinary skill in the art will recognize a variety of transfer processes and transfer media that may be used in relation to different embodiments of the present invention.

Turning to FIGS. 6a-6b, flow diagrams 600, 699 show a method for data reconstruction based data processing in accordance with some embodiments of the present invention. Following flow diagram 600 of FIG. 6a, an analog input is received (block 605). The analog input may be derived from, for example, a storage medium or a data transmission channel. Based upon the disclosure provided herein, one of ordinary skill in the art will recognize a variety of sources of the analog input. The analog input is converted to a series of digital samples (block 610). This conversion may be done using an analog to digital converter circuit or system as are known in the art. Of note, any circuit known in the art that is capable of converting an analog signal into a series of digital values representing the received analog signal may be used. The resulting digital samples are equalized to yield an equalized output (block 615). In some embodiments of the present invention, the equalization is done using a digital finite impulse response circuit as are known in the art. Based upon the disclosure provided herein, one of ordinary skill in the art will recognize a variety of equalizer circuits that may be used in place of such a digital finite impulse response circuit to perform equalization in accordance with different embodiments of the present invention. The equalized output is buffered (block 620).

It is determined whether a data detector circuit is available to process a data set (block 625). Where a data detector circuit is available to process a data set (block 625), the next equalized output from the buffer is accessed for processing (block 630). This equalized output includes a data set corresponding to a purged output from block 530 of FIG. 5. The data detector circuit may be, for example, a Viterbi algorithm data detector circuit or a maximum a posteriori data detector circuit. A data detection algorithm is applied to the accessed equalized output (scaled or not) by the data detector circuit to yield a detected output (block 635). the data detection algorithm may be, but is not limited to, a maximum a posteriori data detection algorithm as is known in the art. The detected output is stored to a central queue memory circuit where it awaits processing by a data decoder circuit (block 645).

Turning to FIG. 6b and following flow diagram 699, it is determined whether a data decoder circuit is available (block 601) in parallel to the previously described data detection process of FIG. 6a. The data decoder circuit may be, for example, a low density parity check data decoder circuit as are known in the art. Where the data decoder circuit is available (block 601) the next derivative of a detected output is selected from the central queue memory circuit (block 606). The derivative of the detected output may be, for example, an interleaved (shuffled) version of a detected output from the data detector circuit.

It is determined whether it is the first global iteration being applied to the currently processing data set (block 602). Where it is the first global iteration being applied to the currently processing data set (block 602), the derivative of the detected output accessed from the central memory is padded with 0s in the positions corresponding to the extra bits purged during the encoding process described above in relation to FIG. 5, and corresponding soft data (e.g., log likelihood data) indicating a low probability that the added 0s have been correctly detected (block 617). In addition, the known added padded bits purged during the encoded process described above in relation to FIG. 5 are also added in their respective positions along with soft data (e.g., log likelihood data) indicating a high probability that the known added padding bits have been correctly detected. The resulting padded output is a reconstructed output corresponding to the graphic described in relation to FIG. 3d.

Alternatively, where it is the second or later global iteration being applied to the currently processing data set (block 602), instances of a previous decoded output (i.e., the soft data corresponding to the instances of the previous decoded output) is scaled to yield a scaled output (block 607). In one particular embodiment of the present invention, the applied scalar value is less than unity. Applying a scalar value less than unity results in a higher probability that the data decoding process will modify the instances of the previous decoded output. In one particular case, the scalar value is 0.25. As more fully described below in relation to block 622, the instances of the previous decoded output correspond to bit or element locations of the extra bits beyond the LDPC encoder boundary that were purged as part of the encoding process discussed above in relation to FIG. 5. These scaled bits or elements are padded to the derivative of the detected output accessed from the central memory in their respective locations, and the known added padding bits purged during the encoding process discussed above in relation to FIG. 5 are also added in their respective locations along with soft data (e.g., log likelihood data) indicating a high probability that the known added padding bits have been correctly detected to yield a padded output (block 612). The resulting padded output is a reconstructed output corresponding to the graphic described in relation to FIG. 3d.

A first local iteration of a data decoding algorithm is applied by the data decoder circuit to the padded output to yield a decoded output (block 611). It is then determined whether the decoded output converged (e.g., resulted in the originally written data as indicated by the lack of remaining unsatisfied checks) (block 616). Where the decoded output converged (block 616), it is provided as a decoded output codeword to a hard decision output buffer (e.g., a re-ordering buffer) (block 621). It is determined whether the received output codeword is either sequential to a previously reported output codeword in which case reporting the currently received output codeword immediately would be in order, or that the currently received output codeword completes an ordered set of a number of codewords in which case reporting the completed, ordered set of codewords would be in order (block 656). Where the currently received output codeword is either sequential to a previously reported codeword or completes an ordered set of codewords (block 656), the currently received output codeword and, where applicable, other codewords forming an in order sequence of codewords are provided to a recipient as an output (block 661).

Alternatively, where the decoded output failed to converge (e.g., errors remain) (block 616), it is determined whether the number of local iterations already applied equals the maximum number of local iterations (block 626). In some cases, a default seven local iterations are allowed per each global iteration. Based upon the disclosure provided herein, one of ordinary skill in the art will recognize another default number of local iterations that may be used in relation to different embodiments of the present invention. Where another local iteration is allowed (block 626), the data decoding algorithm is re-applied to the selected data set using the decoded output as a guide to update the decoded output (block 631), and the processes of blocks starting at block 616 are repeated for the next local iteration.

Alternatively, where all of the local iterations have occurred (block 626), it is determined whether all of the global iterations have been applied to the currently processing data set (block 636). Where the number of global iterations has not completed (block 636), the portion of the decoded output corresponding to the derivative of the detected output is selected from the central queue memory circuit in block 606 are stored back to the central memory to await the next global iteration (block 641), and the instances of the decoded output corresponding to the padded output (i.e., the extra bits beyond the boundary shown in FIG. 3d) are stored to the buffer as the previous decoded output (block 622). Alternatively, where the number of global iterations has completed (block 636), an error is indicated and the data set is identified as non-converging (block 646).

It should be noted that the various blocks discussed in the above application may be implemented in integrated circuits along with other functionality. Such integrated circuits may include all of the functions of a given block, system or circuit, or a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, the invention provides novel systems, devices, methods and arrangements for out of order data processing. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. A data processing system, the data processing system comprising:
a first data encoder circuit operable to encode a data set to yield a first encoded output, wherein the first encoded output includes at least one element beyond the end of a desired boundary;
a bit padding circuit operable to add at least one element to the first encoded output to yield a padded output complying with the desired boundary;
a second data encoder circuit operable to encode the padded output to yield a second encoded output;
a bit purging circuit operable to eliminate the at least one element beyond the end of the desired boundary and the at least one element added to the first encoded output from the second encoded output to yield a purged output;
a data decoder circuit operable to:
receive a first decoder input corresponding to the purged output;
reconstruct a second decoder input corresponding to the second encoded output; and
apply a data decoding algorithm to the second decoder input to yield a decoded output.

2. The data processing system of claim 1, wherein the system further comprises:
a data detector circuit operable to apply a data detection algorithm to a detector input corresponding to the purged output to yield a detected output; and
wherein the first decoder input is derived from the detected output.

3. The data processing system of claim 2, wherein the decoded output is a first decoded output, wherein the detected output is a first detected output, and wherein:
the data decoder circuit is further operable to provide a second decoded output including elements of the first decoded output corresponding to the detected output, and to provide a third decoded output including elements of the first decoded output corresponding to the at least one element added to the first encoded output to yield the padded output; and
the data detector circuit is further operable to re-apply the data detection algorithm to the detector input guided by the second decoded output to yield a second detected output.

4. The data processing system of claim 3, wherein the data decoder circuit is further operable to:
receive a third decoder input corresponding to the second detected output;
scale the third decoded output to yield a scaled output;
augment the third decoder input with the scaled output to yield a fourth decoder input; and
re-apply the data decoding algorithm to the fourth decoder input to yield a fourth decoded output.

5. The data processing system of claim 2, wherein the data detector circuit is selected from a group consisting of: a maximum a posteriori data detector circuit, and a Viterbi algorithm data detector circuit.

6. The data processing system of claim 1, wherein the data decoder circuit is a low density data decoder circuit.

7. The data processing system of claim 1, wherein the system is implemented as an integrated circuit.

8. The data processing system of claim 1, wherein the system is implemented as part of device selected from a group consisting of: a storage device, and a communication device.

9. A data processing system, the data processing system comprising:
a first data encoder circuit operable to encode a data set to yield a first encoded output, wherein the first encoded output includes at least one element beyond the end of a desired boundary;
a bit padding circuit operable to add at least one element to the first encoded output to yield a padded output complying with the desired boundary;
a second data encoder circuit operable to encode the padded output to yield a second encoded output; and
a bit purging circuit operable to eliminate the at least one element beyond the end of the desired boundary and the at least one element added to the first encoded output from the second encoded output to yield a purged output.

10. The data processing system of claim 9, wherein the first data encoder circuit is a run length limited encoder circuit.

11. The data processing system of claim 9, wherein the second data encoder circuit is a low density parity check encoder circuit.

12. The data processing system of claim 9, wherein the desired boundary is an integral number of widths of data accepted by the second data encoder circuit.

13. The data processing system of claim 12, wherein the number of elements beyond the end of a desired boundary including the at least one element beyond the end of a desired boundary is represented as n, and wherein the number of elements padded including the at least one element to the first encoded output to yield the padded output is calculated in accordance with the following equation:
width of data accepted by the second data encoder circuit minus n.

14. The data processing system of claim 9, wherein the data processing system further comprises:
a data decoder circuit operable to:
receive a first decoder input corresponding to the purged output;
reconstruct a second decoder input corresponding to the second encoded output; and
apply a data decoding algorithm to the second decoder input to yield a decoded output.

15. The data processing system of claim 9, wherein the data processing system further comprises:
a data transfer circuit operable to transfer the purged output, wherein the data transfer circuit is selected from a group consisting of: a data write circuit operable to write a representation of the purged output to a storage medium, and a data transmission circuit operable to transmit a representation of the purged output via a communication medium.

16. The data processing system of claim 15, wherein the data transfer circuit is the data write circuit operable to write a representation of the purged output to a storage medium; and wherein the storage medium includes both a magnetic storage medium and a solid state storage medium.

17. A data processing system, the data processing system comprising:
a data decoder circuit operable to:
receive a first decoder input corresponding to a first encoded output;
reconstruct a second decoder input by adding at least one element to the first decoder input, wherein the at least one element added to the first decoder input corresponds to a difference between the first encoded output and a second encoded output; and
apply a data decoding algorithm to the second decoder input to yield a decoded output.

18. The data processing system of claim 17, wherein the system further comprises:
a first data encoder circuit operable to encode a data set to yield the first encoded output, wherein the first encoded output includes at least one element beyond the end of a desired boundary;
a bit padding circuit operable to add at least one element to the first encoded output to yield a padded output complying with the desired boundary;
a second data encoder circuit operable to encode the padded output to yield the second encoded output; and
a bit purging circuit operable to eliminate the at least one element beyond the end of the desired boundary and the at least one element added to the first encoded output from the second encoded output to yield a purged output.

19. The data processing system of claim 18, wherein the at least one element added to the first decoder input corresponds to the at least one element beyond the end of the desired boundary.

20. The data processing system of claim 17, wherein the system further comprises:
a data detector circuit operable to apply a data detection algorithm to a detector input corresponding to the first encoded output to yield a detected output; and
wherein the first decoder input is derived from the detected output.

21. The data processing system of claim 20, wherein the data detector circuit is selected from a group consisting of: a maximum a posteriori data detector circuit, and a Viterbi algorithm data detector circuit.

22. The data processing system of claim 20, wherein the decoded output is a first decoded output, wherein the detected output is a first detected output, and wherein:
the data decoder circuit is further operable to provide a second decoded output including elements of the first decoded output corresponding to the detected output, and to provide a third decoded output including elements of the first decoded output corresponding to the at least one element added to the first encoded output to yield the padded output; and
the data detector circuit is further operable to re-apply the data detection algorithm to the detector input guided by the second decoded output to yield a second detected output.

23. The data processing system of claim 22, wherein the data decoder circuit is further operable to:
receive a third decoder input corresponding to the second detected output;
scale the third decoded output to yield a scaled output;
augment the third decoder input with the scaled output to yield a fourth decoder input; and
re-apply the data decoding algorithm to the fourth decoder input to yield a fourth decoded output.

24. The data processing system of claim 23, wherein the data decoder circuit is a low density data decoder circuit.

25. The data processing system of claim 17, wherein the system is implemented as part of device selected from a group consisting of: a storage device, and a communication device.
